(19) United States
(12) Patent Application Publication
(10) Pub. No.: US 2019/0006213 A1
(43) Pub. Date: Jan. 3, 2019

(54) CHEMICAL SUPPLYING UNIT, SUBSTRATE TREATMENT APPARATUS, AND METHOD OF TREATING SUBSTRATE USING THE SUBSTRATE TREATMENT APPARATUS

(71) Applicant: Semes Co., Ltd., Cheonan-si (KR)

(72) Inventors: Tae Suk YUN, Cheonan-si (KR); Byung Un Kim, Cheonan-si (KR); Chang Yul Cho, Cheonan-si (KR)

(73) Assignee: Semes Co., Ltd., Cheonan-si (KR)

(21) Appl. No.: 16/126,188

(22) Filed: Sep. 10, 2018

Related U.S. Application Data
(62) Division of application No. 14/228,512, filed on Mar. 28, 2014.

(30) Foreign Application Priority Data
Mar. 29, 2013 (KR) 10-2013-0034692
Jun. 21, 2013 (KR) 10-2013-0071731

(51) Int. Cl. H01L 21/67

(52) U.S. Cl. CPC H01L 21/67253; H01L 21/67051; H01L 21/67017; Y10T 137/86027; Y10T 137/6606

(57) ABSTRACT

Provided is a substrate treatment apparatus including a housing, a supporting unit located inside the housing and supporting a substrate, a nozzle unit supplying chemicals to the substrate disposed on the supporting unit, and a chemical supplying unit supplying the chemicals to the nozzle unit. Herein, the chemical supplying unit includes a chemical supply source, a first tank and a second tank storing the chemicals, a chemical supplying line supplying the chemicals from the chemical supply source to the first tank and the second tank, a chemical discharge line supplying the chemicals from the first tank and the second tank to the nozzle unit, a circulation line allowing the chemicals to circulate through the first tank and the second tank, respectively, a member installed on the circulation line, and a controller controlling the member.

### CROSS-REFERENCE TO RELATED APPLICATIONS

This application is a Divisional Application of U.S. application Ser. No. 14/228,512, filed Mar. 28, 2014, which claims priority under 35 U.S.C. § 119 of Korean Patent Application No. 10-2013-0034692, filed on Mar. 29, 2013, and 10-2013-0071731, filed on Jun. 21, 2013, the entire contents of each of which are hereby incorporated by reference.

### BACKGROUND OF THE INVENTION

The present invention disclosed herein relates to a chemical supplying unit for supplying chemicals to a substrate, a substrate treatment apparatus including the chemical supplying unit, and a method of treating a substrate using the substrate treatment apparatus.

Particles, organic pollutants, and metal pollutants remaining on a surface of a substrate have a great effect on properties of a semiconductor device and production yield. Due thereto, a cleaning process of removing various kinds of pollutants attached to the surface of the substrate is very important in a semiconductor manufacturing process and is performed before and after respective unit processes of manufacturing semiconductors. Generally, cleaning of a substrate includes a chemical treatment process of removing metallic foreign substances, organic materials, or particles remaining one the substrate using chemicals, a rinse process of removing the chemicals remaining on the substrate using deionized water, and a drying process of drying the substrate using a nitrogen gas.

In the chemical treatment process, a chemical supplying unit provides a nozzle unit with chemicals. Generally, the chemical supplying unit is connected to a circulation line and the circulation line is provided with a pump and a heater. It is necessary to allow chemicals in a tank to satisfy a set condition in order to quickly supply the chemicals to a nozzle if necessary. Accordingly, the pump installed on the circulation line is set to allow strokes per minute to be high, thereby consuming a large amount of energy.

### SUMMARY OF THE INVENTION

The present invention provides a substrate treatment apparatus capable of variably controlling a chemical supplying state according to a working condition.

The present invention also provides a substrate treatment apparatus capable of reducing energy.

Effects of the present invention are not limited to the described above, and effects not mentioned above will be clearly understood by a person of ordinary skill in the art from the specification and the attached drawings.

Embodiments of the present invention provide substrate treatment apparatuses including a housing, a supporting unit located inside the housing and supporting a substrate, a nozzle unit supplying chemicals to the substrate disposed on the supporting unit, and a chemical supplying unit supplying the chemicals to the nozzle unit. Herein, the chemical supplying unit includes a chemical supply source, a first tank and a second tank storing the chemicals, a chemical supplying line supplying the chemicals from the chemical supply source to the first tank and the second tank, a chemical discharge line supplying the chemicals from the first tank and the second tank to the nozzle unit, a circulation line allowing the chemicals to circulate through the first tank and the second tank, respectively, a member installed on the circulation line, and a controller controlling the member. The controller includes first mode and a second mode for controlling the member, and an energy consumption amount is smaller in the second mode than the first mode.

In some embodiments, the controller may maintain the first mode till the chemicals in one of the first tank and the second tank satisfy a process condition and may convert the first mode into the second mode and maintain the second mode after satisfying the process condition.

In other embodiments, the controller may maintain the first mode in initial stages and may convert the first mode into the second mode and maintain the second mode after that.

In still other embodiments, the member may include a pump, and the controller may control strokes per minute of the pump to be lower in the second mode than the first mode.

In even other embodiments, the member may include a heater, and the controller may control a temperature of the heater to be lower in the second mode than the first mode.

In yet other embodiments, the member may include a pump and a heater, and the controller may control strokes per minute of the pump and a temperature of the heater to be lower in the second mode than the first mode.

In further embodiments, the circulation line may include a first line connected to a bottom of the first tank, a second line connected to a bottom of the second tank, a third line connected to a top of the first tank, a fourth line connected to a top of the second tank, and a common line connected to all the first line, the second line, the third line, and the fourth line. Herein, the member may be installed on the common line, the chemicals in the first tank may circulate through the first line, the common line, and the third line and the chemicals in the second tank may circulate through the second line, the common line, and the fourth line.

In other embodiments of the present invention, chemical supplying units supplying chemicals to be supplied to a substrate include a chemical supply source, a tank storing the chemicals, a chemical supplying line supplying the chemicals from the chemical supply source to the tank, a chemical discharge line supplying the chemicals from the tank to the nozzle unit, a circulation line allowing the chemicals to circulate through the tank, a member installed on the circulation line, and a controller controlling the member. Herein, the controller may include a first mode and a second mode for controlling the member, and an energy consumption amount may be smaller in the second mode than the first mode.

In some embodiments, the controller may maintain the first mode till the chemicals in one of the first tank and the second tank satisfy a process condition and may convert the first mode into the second mode and maintain the second mode after satisfying the process condition.

In other embodiments, the controller may maintain the first mode in initial stages and may convert the first mode into the second mode and maintain the second mode after that.

In still other embodiments, the member may include a pump, and the controller may control strokes per minute of the pump to be lower in the second mode than the first mode.

In even other embodiments, the member may include a heater, and the controller may control a temperature of the heater to be lower in the second mode than the first mode.

In yet other embodiments, the member may include a pump and a heater, and the controller may control strokes per minute of the pump and a temperature of the heater to be lower in the second mode than the first mode.

In further embodiments, the tank may include a first tank and a second tank, and the chemical supply source may include a first chemical supply source supplying first chemicals and a second chemical supply source supplying second chemicals.

In still other embodiments of the present invention, methods of treating a substrate, in which chemicals supplied into a tank are controlled circulating through a circulation line connected to the tank while being controlled to be in a first mode till satisfying a process condition and to be in a second mode different from the first mode after satisfying the process condition.

In some embodiments, an energy consumption amount may be smaller in the second mode than the first mode.

In other embodiments, the circulation line may be installed with a heater for controlling a temperature of the chemicals, and the temperature may be controlled to be lower in the second mode in the first mode.

In still other embodiments, the circulation line may be installed with a pump for controlling a flow amount of the chemicals, and strokes per minute of the pump may be controlled to be lower in the second mode in the first mode.

In even other embodiments, the circulation line may be installed with a pump for controlling a flow amount of the chemicals and a heater for controlling a temperature of the chemicals, and strokes per minute of the pump and the temperature may be controlled to be lower in the second mode in the first mode.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a front view schematically illustrating a substrate treatment system provided with a substrate treatment apparatus according to an embodiment of the present invention;

FIG. 2 is a cross-sectional view of the substrate treatment apparatus of FIG. 1;

FIG. 3 is a view of a chemical supplying unit according to an embodiment of the present invention;

FIG. 4 is a view illustrating a circulation of chemicals through a circulation line of FIG. 3;

FIG. 5 is a view of a controller controlling a member of FIG. 3;

FIG. 6 is a view illustrating strokes of the pump per minute in the supplying mode;

FIG. 7 is a view illustrating a temperature of a heater in the supplying mode

FIG. 8 is a view illustrating a power consumption amount in a supplying mode;

FIGS. 9 and 10 are views of a controller controlling the member ;

FIG. 11 is a view illustrating a chemical supplying unit according to another embodiment of the present invention;

FIG. 12 is a view illustrating a chemical supplying unit according to still another embodiment of the present invention; and

FIGS. 13 to 18 are views sequentially illustrating a method of treating a wafer by using the chemical supplying unit of FIG. 3.

### DETAILED DESCRIPTION OF PREFERRED EMBODIMENTS

Hereinafter, embodiments of the present invention will be described in detail with reference to the attached drawings. The embodiments of the present invention may be modified to be various forms, and the scope of the present invention is not limited to the following embodiments. The embodiments are provided to more perfectly explain the present invention to a person of ordinary skill in the art. Accordingly, shapes of elements in the drawings are exaggerated for more accurate descriptions.

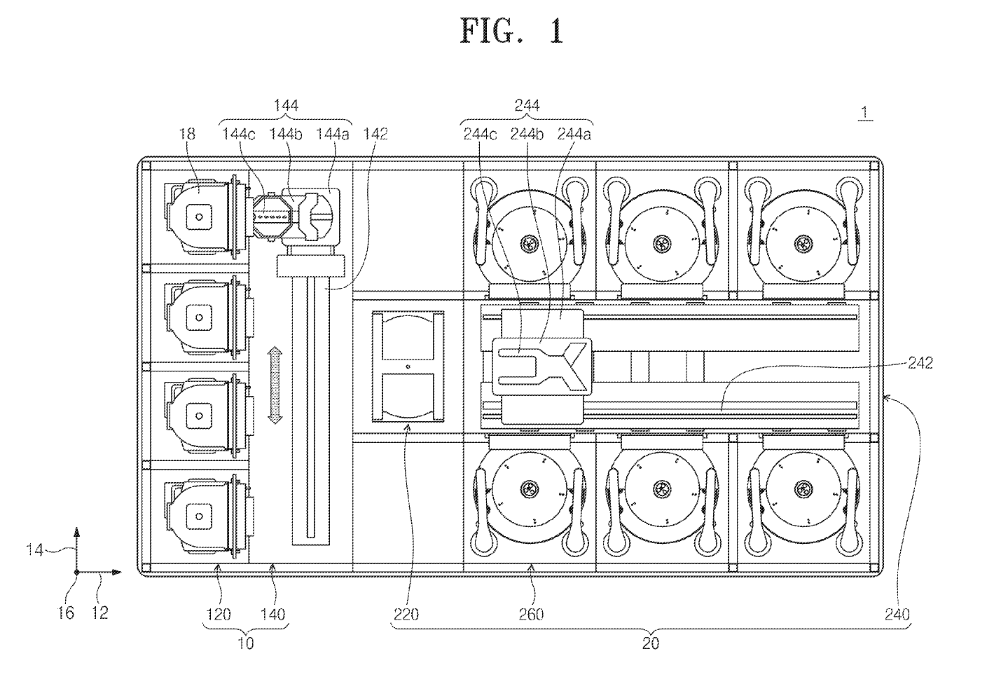

Hereinafter, the embodiments will be described in detail with reference to FIGS. 1 to 18.

FIG. 1 is a top view schematically illustrating a substrate treatment system 1.

Referring to FIG. 1, the substrate treatment system 1 includes an index module 10 and a process treatment module 20 and the index module 10 includes a load port 120 and a transfer frame 140. The load port 120, the transfer frame 140, and the process treatment module 20 are sequentially arranged in a row. Hereinafter, a direction arranged with the load port 120, the transfer frame 140, and the process treatment module 20 will be designated as a first direction 12. Also, in a top view, a direction perpendicular to the first direction 12 is designated as a second direction 14 and a direction perpendicular to a plane including the first direction 12 and the second direction 14 is designated as a third direction 16.

A carrier 130 containing a substrate W is mounted on the load port 140. The load port 120 is provided in a plurality thereof and arranged in a row along the second direction 14. In FIG. 1, it is shown that four load ports 120 are provided. However, the number of the load ports 120 may increase or decrease according to conditions such as process efficiency and a footprint of the process treatment module 20. The carrier 130 is formed with a slot (not shown) provided to support an edge of a substrate. The slot is provided in a plurality thereof in the third direction, and substrates are located in the carrier 130 to be deposited in the third direction while being separate from one another. As the carrier 130, a front opening unified pod (FOUP) may be used.

The process treatment module 20 includes a buffer unit 220, a transfer chamber 240, and a process chamber 260. The transfer chamber 240 is disposed to allow a longitudinal direction thereof to be parallel to the first direction 12. In the second direction 14, the process chambers 260 are disposed on one side and another side of the transfer chamber 240, respectively. The process chambers 260 located on the one side of the transfer chamber 240 and the process chambers 260 located on the other side of the transfer chamber 240 are provided to be symmetrical to one another based on the transfer chamber 240. Some of the process chambers 260 are arranged in the longitudinal direction of the transfer chamber 240. Also, some of the process chambers 260 are arranged to overlap one another. That is, the process chambers 260 may be arranged on the one side of the transfer chamber 240 in an array of A×B, in which A and B are natural number. In this case, A is the number of the process chambers 260 provided in a row in the first direction 12 and B is the number of the process chambers 260 provided in a row in the second direction 16. When the process chambers 260 are provided four or six on the one side of the transfer chamber 240, the process chambers 260 may be arranged in an array of 2×2 or 3×2. The number of the process chambers 260 may increase or decrease. Different from the described above, the process chambers 260 may be provided only on the one side of the transfer chamber 240. Different from the described above, the process chambers 260 may be provided as one story on the one side or the both sides of the transfer chamber 240.

The buffer unit 220 is disposed between the transfer frame 140 and the transfer chamber 240. The buffer unit 220 provides a space between the transfer chamber 240 and the transfer frame 140, in which the substrate W stays before being retransferred. The buffer unit 220 is provided with a slot (not shown) therein, on which the substrate W is disposed. The slots are provided in a plurality thereof in the third direction 16 to be separate from one another. In the buffer unit 220, a surface facing the transfer frame 140 and a surface facing the transfer chamber 240 are open, respectively.

The transfer frame 140 retransfers the substrate W between the carrier 130 mounted on the load port 120 and the buffer unit 220. The transfer frame 140 is provided with an index rail 142 and an index robot 144. The index rail 142 is arranged to allow a longitudinal direction thereof to be parallel to the second direction 14. The index robot 144 is installed on the index rail 142 and straightly moves along the index rail 142 in the second direction 14. The index robot 144 includes a base 144a, a body 144b, and an index arm 144c. The base 144a is installed to be movable along the index rail 142. The body 144b is coupled with the base 144a. The body 144b is provided on the base 144a to be movable in the third direction 16. Also, the body 144b is provided on the base 144a to be rotatable.

The index arm 144c is coupled with the body 144b and is provided to be movable forward and backward with respect to the body 144b. The index arm 144c is provided in a plurality thereof to be individually operated, respectively. The index arms 144c are deposited in the third direction 16 while being separated from one another. Some of the index arms 144c may be used for retransferring the substrate W from the process treatment module 20 to the carrier 130, others may be used for retransferring the substrate W from the carrier 130 to the process treatment module 20. This may prevent particles generated from the substrate W before being process-treated from being attached to the substrate W after being process-treated while the index robot 144 is bringing in and taking out the substrate W.

The transfer chamber 240 retransfers the substrate W between the buffer unit 220 and the process chamber 260 and between the process chambers 260. The transfer frame 240 is provided with a guide rail 242 and a main robot 244. The guide rail 242 is disposed to allow a longitudinal direction thereof to be parallel to the first direction 12. The main robot 244 is installed on the guide rail 242 and straightly moves along the guide rail 242 in the first direction 12. The main robot 244 includes a base 244a, a body 144b, and a main arm 144c. The base 244a is installed to be movable along the guide rail 242. The body 144b is coupled with the base 244a. The body 244b is provided on the base 244a to be movable in the third direction 16. Also, the body 244b is provided to be rotatable on the base 244a. The main arm 244c is coupled with the body 244b and is provided to be movable forward and backward with respect to the body 244b. The main arm 244c is provided in a plurality thereof to be individually operated, respectively. The main arms 244c are deposited in the third direction 16 while being separate from one another. The main arm 244c used for retransferring the substrate W from the buffer unit 220 to the process chamber 260 may be different from the main arm 244c used for retransferring the substrate W from the process chamber 260 to the buffer unit 220.

In the process chamber 260, a substrate treatment apparatus performing a cleaning process on the substrate W is provided. The substrate treatment apparatus 300 provided in each of the process chambers 260 may have a configuration different according to a kind of a cleaning process performed thereby. Selectively, the substrate treatment apparatuses 300 in the respective process chambers 260 may have the same configuration. Selectively, the process chambers 260 are divided into a plurality of groups, in which the substrate treatment apparatuses 300 provided in the process chambers 260 belonging to the same group may have the same configuration and the substrate treatment apparatuses 300 provided in the process chambers 260 belonging to different groups may have different configurations from one another. For example, when the process chambers 260 are classified into two groups, the process chambers 260 of a first group may be provided on the one side of the transfer chamber 240 and the process chambers 260 of a second group may be provided on the other side of the transfer chamber 240. Selectively, the process chambers 260 of the first group may be provided on a lower level of both the one and the other sides of the transfer chamber 240 and the process chambers 260 of the second group may be provided on an upper level thereof. The process chambers 260 of the first group and the process chambers 260 of the second group may be classified according to a type of chemicals or a type of a cleaning method to be used, respectively.

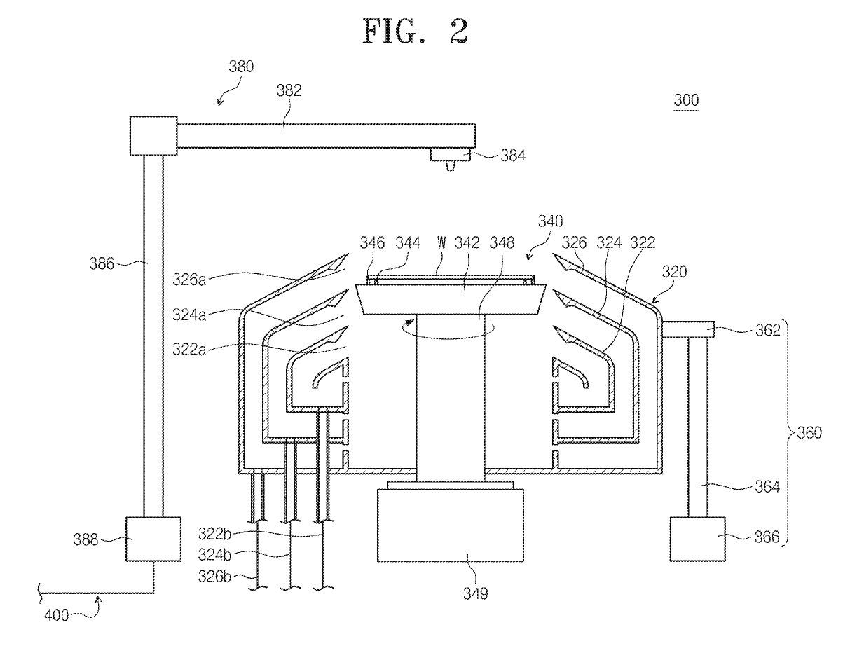

hereinafter, an example of the substrate treatment apparatus 300 cleaning the substrate W using chemicals will be described. FIG. 2 is a cross-sectional view of the substrate treatment apparatus 300 according to an embodiment of the present invention. Referring to FIG. 2, the substrate treatment apparatus 300 includes a housing 320, a supporting unit 340, an elevation unit 360, a nozzle unit 380, and a chemical supplying unit 400.

The housing 320 provides a space for performing a process of treating a substrate and has an open top. The housing 320 includes an inner collection container 322, an intermediate collection container 324, and an outer collection container 326. The respective collection containers 322, 324, and 326 collect different kinds of chemicals used in processes. The inner collection container 322 has a ring shape surrounding the supporting unit 340, the intermediate collection container 324 has a ring shape surrounding the inner collection container 322, and the outer collection container 326 has a ring shape surrounding the intermediate collection container 324. An inner space 322a in the inner collection container 322, an interspace 324a between the inner collection container 322 and the intermediate collection container 324, an interspace 326a between the intermediate collection container 324 and the outer collection container 326 function as inlets for allowing chemicals to flow into the inner collection container 322, the intermediate collection container 324, and the outer collection container 326, respectively. The respective collection containers 322, 324, and 326 are connected to collection lines 322b, 324b, and 326b perpendicularly extending downwards from bottoms thereof. The respective collection lines 322b, 324b, and 326b discharge the chemicals flowing thereinto through the respective collection containers 322, 324, and 326. The discharged chemicals may be reused through an external chemical regeneration system (not shown).

The supporting unit 340 is disposed in the housing 320. The supporting unit 340 supports and rotates the substrate W while performing a process. The supporting unit 340 includes a body 342, a supporting pin 344, a chucking pin 346, and a supporting shaft 348. The body 342 has an approximately circular top surface in a top view. A bottom of the body 342 is fixed and coupled with the supporting shaft 348 rotatable by a motor 349. The supporting pin 344 is provided in a plurality thereof. The supporting pins 334 are disposed on an edge of the top surface of the body 342 with certain intervals and project upwards from the body 342. The supporting pins 334 are disposed to allow a combination thereof to entirely have a ring shape. The supporting pins 334 support an edge of a rear of the substrate W to allow the substrate W to be separate from the top surface of the body 342 with a certain distance. The chucking pin 346 is provided in a plurality thereof. The chucking pin 346 is disposed to be separate from a center of the body 342 further than the supporting pin 344. The chucking pin 346 is provided to project from the body 342. The chucking pin 346 supports a side of the substrate W not to be separated laterally from a precise location while a supporting unit 340 is rotating. The chucking pin 346 is provided to be straightly movable between a standby position and a supporting position in a radial direction of the body 342. The standby position is a separate from the center of the body 342 further than the supporting position. While the substrate is being loaded on or unloaded from the supporting unit 340, the chucking pin 346 is in the standby position. While performing a process on the substrate W, the chucking pin 346 is in the supporting position. In the supporting position, the chucking pin 346 is in contact with the side of the substrate W.

The elevation unit 360 straightly transfers the housing up and down. As the housing 320 is transferred up and down, a relative height of the container 320 with respect to the supporting unit 340 is changed. The elevation unit 360 includes a bracket 362, a transfer shaft 364, and a driver 366. The bracket 362 is fixed to an outer wall of the housing 320 and is fixed and coupled with the transfer shaft 364 transferred up and down by the driver 366. When the substrate W is disposed on the supporting unit 340 or elevated from the supporting unit 340, the housing 320 descends to allow the supporting unit 340 to project upwards from the housing 320. Also, while performing the process, according to the kind of the chemicals supplied to the substrate W, the height of the housing 320 is controlled to allow the chemicals to flow into a preset collection container 360. For example, while being treated using first chemicals, the substrate W is located at a height corresponding to the inner space 322a of the inner collection container 322. Also, while being treated using second chemicals and then third chemicals, the substrate W may be located at heights corresponding to the interspace 324a between the inner collection container 322 and the intermediate collection container 324 and corresponding to the interspace 326a between the intermediate collection container 324 and the outer collection container 326, respectively. Different from the described above, the elevation unit 360 may transfer the supporting unit 340 up and down.

The nozzle unit 380 supplies the chemicals to the substrate W while treating the substrate W. The nozzle unit 380 includes a nozzle supporting bar 382, a nozzle 384, a supporting shaft 386, and a driver 388. The supporting shaft 386 is provided to allow a longitudinal direction to be in the third direction 16 and is coupled with the driver 388 at a bottom of the supporting shaft 386. The driver 388 rotates and elevates the supporting shaft 386. The nozzle supporting bar 382 is perpendicularly coupled with an opposite side of the bottom of the supporting shaft 386 coupled with the driver 388. The nozzle 384 is installed on a bottom of an end of the nozzle supporting bar 382. The nozzle 384 is transferred by the driver 388 between a process position and a standby position. The process position is a position, in which the nozzle 384 is disposed perpendicularly to the top of the housing 320. The standby position is a position, in which the nozzle 384 is out of being perpendicular to the top of the housing 320. The nozzle unit 380 may be provided one or in a plurality thereof. When the nozzle unit 380 is provided in the plurality thereof, chemicals, a rinse solution, or an organic solvent may be provided through different nozzle units 380. The rinse solution may be deionized water, and the organic solvent may be one of a mixture of isopropyl alcoholic steam and an inert gas and an isopropyl alcoholic solution.

A chemical supplying unit 4100 supplies chemicals to the nozzle unit 380. For example, chemicals may be one of an acid solution such as hydrofluoric acid, sulfuric acid, nitric acid, and phosphoric acid, an alkaline solution containing potassium hydroxide, sodium hydroxide, ammonium, and deionized water.

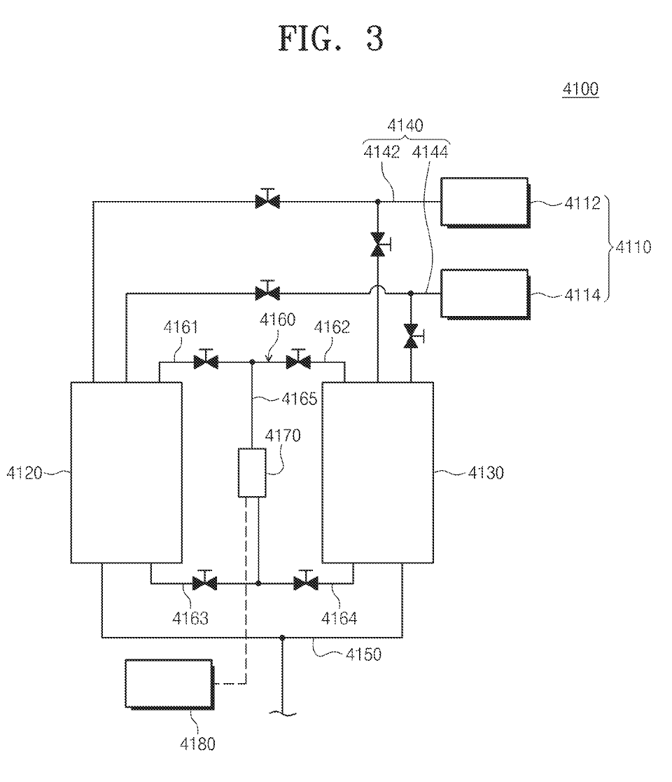

Hereinafter, an exemplary embodiment of the chemical supplying unit 400 will be described. FIG. 3 is a view of the chemical supplying unit 4100 according to an embodiment of the present invention.

Referring to FIG. 3, the chemical supplying unit 4100 includes a chemical supply source 4110, a first tank 4120, a second tank 4130, chemical supplying line 4140, a chemical discharge line 4150, a circulation line 4160, a member 4170, and a controller 4180.

The chemical supply source 4110 stores chemicals used for a process and supplies the chemicals to one of the first tank 4120 and the second tank 4130. The chemical supply source 4110 may include a first chemical supply source 4112 storing first chemicals and a second chemical supply source 4114 storing second chemicals.

The first tank 4120 and the second tank 4130 have approximately identical structure. The first tank 4120 and the second tank 4130 store chemicals. While one of the first tank 4120 and the second tank 4130 is supplying chemicals to the nozzle unit 380, another thereof exchanges chemicals.

The chemical supplying line 4140 may include a first chemical supplying line 4142 and a second chemical supplying line 4144. The first chemical supplying line 4142 connects the first chemical supply source 4110 to the first tank 4120 and the second tank 4130, respectively. The first chemical supplying line 4142 supplies chemicals from the first chemical supply source 4112 to the first tank 4120 and the second tank 4130, respectively. The second chemical supplying line 4144 connects the second chemical supply source 4114 to the first tank 4120 and the second tank 4130, respectively. The second chemical supplying line 4144 supplies chemicals from the second chemical supply source 4114 to the first tank 4120 and the second tank 4130, respectively.

The chemical discharge line 4150 connects the first tank 4120 and the second tank 4130 to the nozzle unit 380. The chemical discharge unit 4150 supplies chemicals to the nozzle unit 380.

Referring to FIG. 3, a mixture of the first chemicals and the second chemicals is stored in the first tank 4120 and the second tank 4130. Differently, one of the first tank 4120 and the second tank 4130 may store only one chemicals. The chemicals are uniformly mixed flowing through the circulation line 4160.

The circulation line 4160 includes a first line 4161, a second line 4162, a third line 4163, a fourth line 4164, and a common line 4165. The circulation line 4160 allows the chemicals of the first tank 4120 and the second tank 4130 to circulate. The first line 4161 is connected to a top surface of the first tank 4120. The second line 4162 is connected to a top surface of the second tank 4130. The third line 4163 is connected to a bottom surface of the first tank 4120. The chemicals of the first tank 4120 flow out through the third line 4163. The fourth line 4164 is connected to a bottom surface of the second tank 4130. The chemicals of the second tank 4130 flow out through the fourth line 4164. The common line 4165 connects all the first line 4161, the second line 4162, the third line 4163, and the fourth line 4164 to one another. The chemicals flowing through the common line 4165 flow into the first tank 4120 through the first line 4161 or flow into the second tank 4130 through the second line 4162.

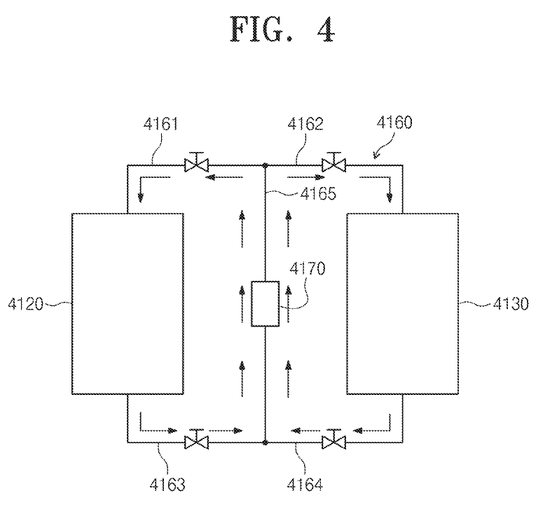

Referring to FIG. 4, the chemicals of the first tank 4120 circulate through the first line 4161, the common line 4165, and the third line 4163. The chemicals of the second tank 4130 circulate through the second line 4162, the common line 4165, and the fourth line 4164.

The circulation line 4160 is installed with the member 4170 thereon. The member 4170 includes a pump 4172 and a heater 4174 as shown in FIG. 5. The pump 4172 adjusts a chemical supply flow by controlling strokes per minute. The heater 4174 controls a temperature of the chemicals. Differently, the member 4170 may include only one of the pump 4172 and the heater 4174.

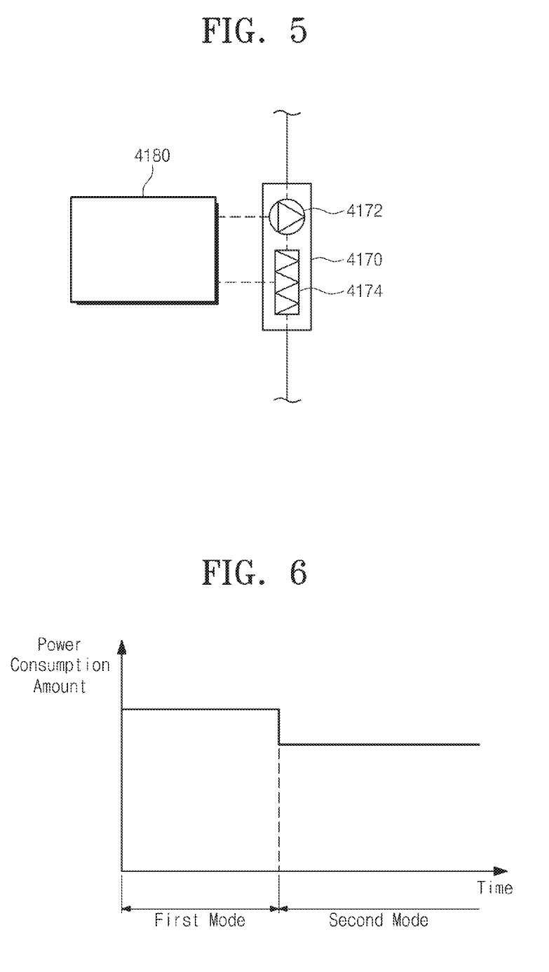

The controller 4180 controls the member 4170 (refer to FIG. 5). The controller 4180 controls the pump 4172 to control the strokes per minute. Also, the controller 4180 controls the heater 4174 to control the temperature of the chemicals. The controller 4180 includes a first mode and a second mode. Referring to FIG. 6, an energy consumption amount is smaller in the second mode than in the first mode.

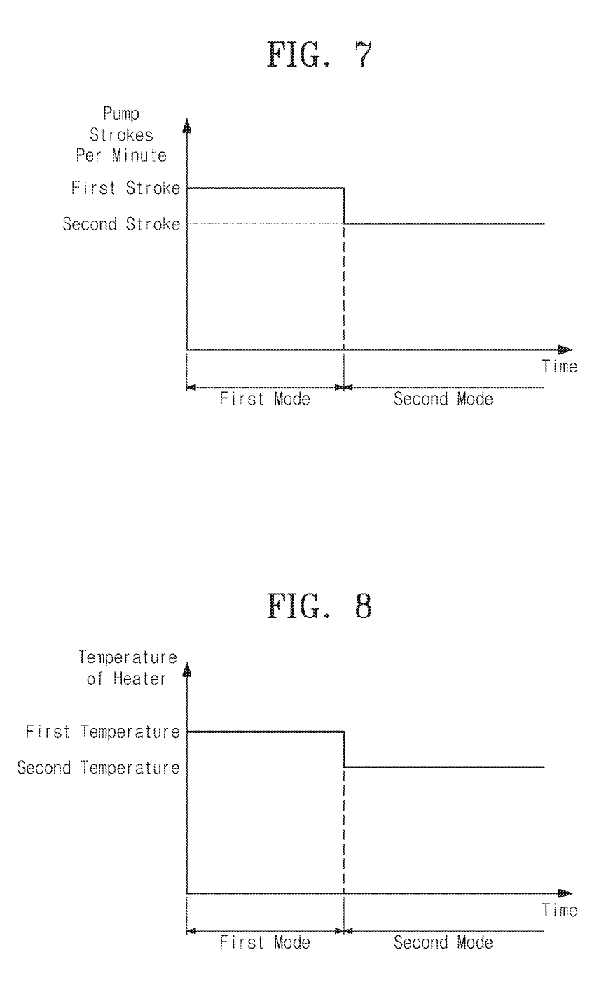

The controller 4180 initially maintains the first mode of the chemicals in one of the first tank 4120 and the second tank 4130, and after that, maintains the second mode. According the embodiment, the controller 4180 maintains the first mode before the chemicals in one of the first tank 4120 and the second tank 4130 satisfy a process condition and maintains the second mode after satisfying the process condition. The process condition indicates one of preset temperature and concentration of the chemicals in one of the first tank 4120 and the second tank 4130. In the first mode, the controller 4180 controls the strokes per minute of the pump 4172 to be fast to allow the chemicals to quickly satisfy the process condition. When the chemicals are allowed to quickly circulate, the chemicals may be quickly mixed and may quickly satisfy the process condition. In the second mode, the controller 4180 controls the strokes per minute of the pump 4172 to be lower than the first mode, thereby maintaining the temperature and concentration as the process condition. As an example, referring to FIG. 7, the strokes per minute may be controlled to be a first stroke in the first mode and may be controlled to be a second stroke in the second mode. The first stroke may be from about 70 to about 100 spm, and the second stroke may be from about 10 to about 30 spm. Also, to quickly satisfy the process condition, the controller 4180 controls the heater 4174 to be at a high temperature in the first mode. Also, in the second mode, the controller 4180 controls the heater 4174 to be at a lower temperature than the first mode. Referring to FIG. 8, the temperature may be controlled to be a first temperature in the first mode and may be controlled to be a second temperature in the second mode. The second temperature may be a process temperature, and the first temperature may be higher than the process temperature.

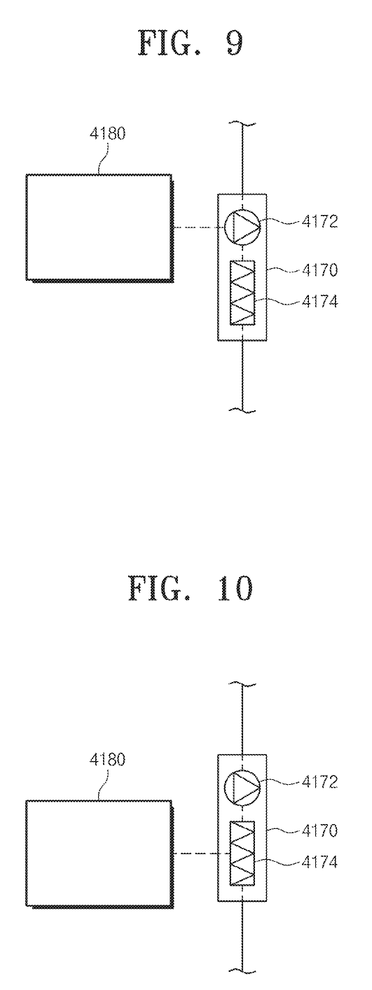

Differently, the controller 4180 may independently control only the pump 4172 of the pump 4172 and the heater 4174 (refer to FIG. 9). Differently, the controller 4180 may independently control only the pump 4172 of the pump 4172 and the heater 4174 (refer to FIG. 10).

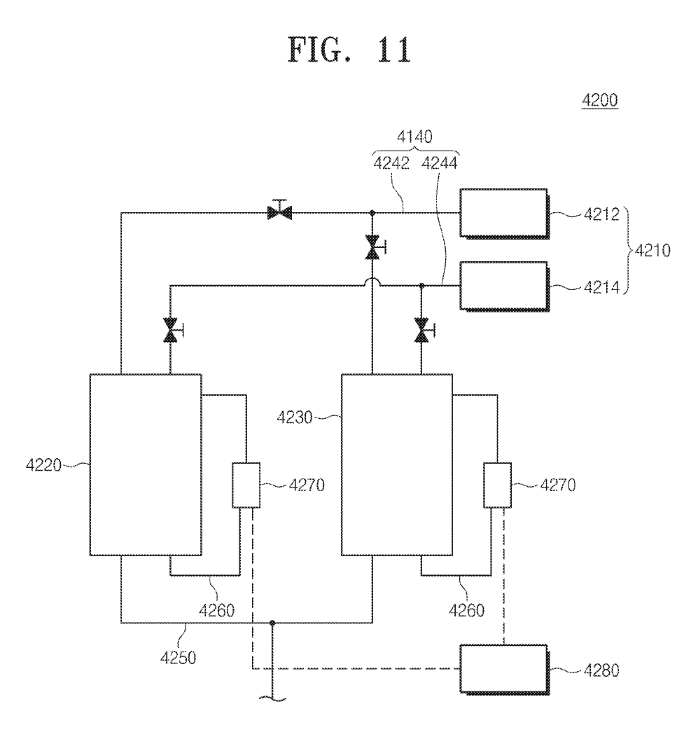

FIG. 11 is a view of a chemical supplying unit 4200 according to another embodiment of the present invention.

The chemical supplying unit 4200 includes a chemical supply source 4210, a first tank 4220, a second tank 4230, a chemical supplying line 4240, a chemical discharge line 4250, a circulation line 4260, a member 4270, and a controller 4280. The chemical supply source 4210, the first tank 4220, the second tank 4230, a first chemical supplying line 4242, a second chemical supplying line 4244, the chemical discharge line 4250, the member 4270, and the controller 4280 may have configurations and shapes approximately identical or similar to the chemical supply source 4110, the first tank 4120, the second tank 4130, the first chemical supplying line 4142, the second chemical supplying line 4144, the chemical discharge line 4150, the member 4170, and the controller 4180. The circulation line 4260 is provided independently to the first tank 4220 and the second tank 4230, respectively. The circulation line 4260 allows the chemicals of the first tank 4220 and the second tank 4230 to circulate, respectively. The circulation line 4260 is installed with the member 4270 thereon.

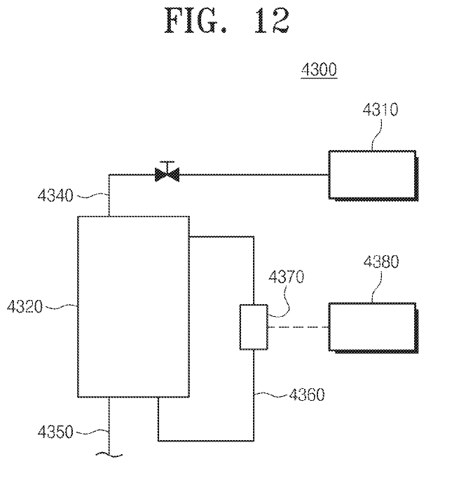

FIG. 12 is a view of a chemical supplying unit 4300 according to still another embodiment of the present invention.

Referring to FIG. 12, the chemical supplying unit 4300 may include a chemical supply source 4310, a tank 4320, a chemical discharge line 4350, a circulation line 4360, a member 4370, and a controller 4380. The chemical supply source 4310, a chemical supplying line 4340, the chemical discharge line 4350, the circulation line 4360, the member 4370, and the controller 4380 may have configurations and shapes approximately identical or similar to the chemical supply source 4210, the chemical discharge line 4250, the circulation line 4260, the member 4270, and the controller 4280 of FIG. 11. As shown in FIG. 12, it is possible to provide only one of the tank 4320 and the chemical supplying line 4340.

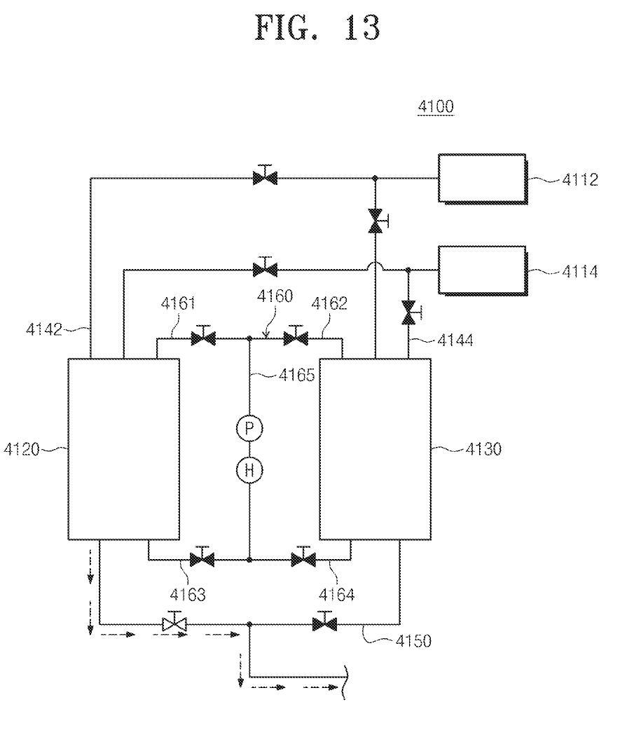

Hereinafter, referring to FIGS. 13 to 18, a method of treating a wafer using the chemical supplying unit 4100 of FIG. 3 will be described. FIGS. 13 to 18 are views sequentially illustrating the method of treating the wafer by using the chemical supplying unit of FIG. 3. Arrows indicate fluid flows. A valve with an inside filled with black indicates a closed valve, and a valve with an empty inside indicates an open valve.

The chemical supplying unit 4100 may be controlled to be in a first mode in initial stages and may be controlled to be in a second mode. As an example, the initial stages may be till satisfying a process condition.

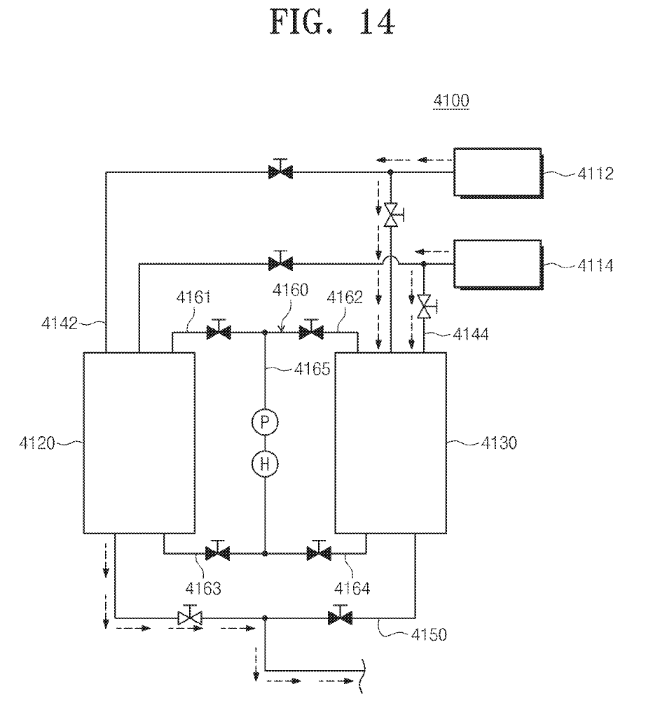

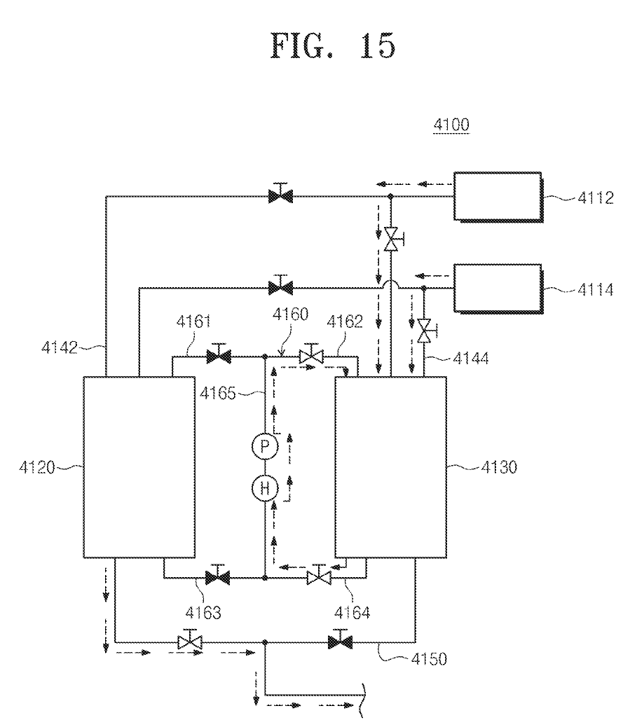

As shown in FIG. 13, chemicals in the first tank 4120 are supplied to the nozzle unit 380 through the chemical discharge line 4150. After that, to allow the second tank 4230 to satisfy the process condition, as shown in FIG. 14, the chemicals in the chemical supply sources 4112 and 4114 are supplied to the second tank 4130 through the chemical supplying lines 4142 and 4144. After that, referring to FIG. 15, the chemicals circulate through the circulation line 4360. The circulation is performed by the pump 4172. During the circulation, the chemicals are heated and are uniformly mixed by the heater 4174.

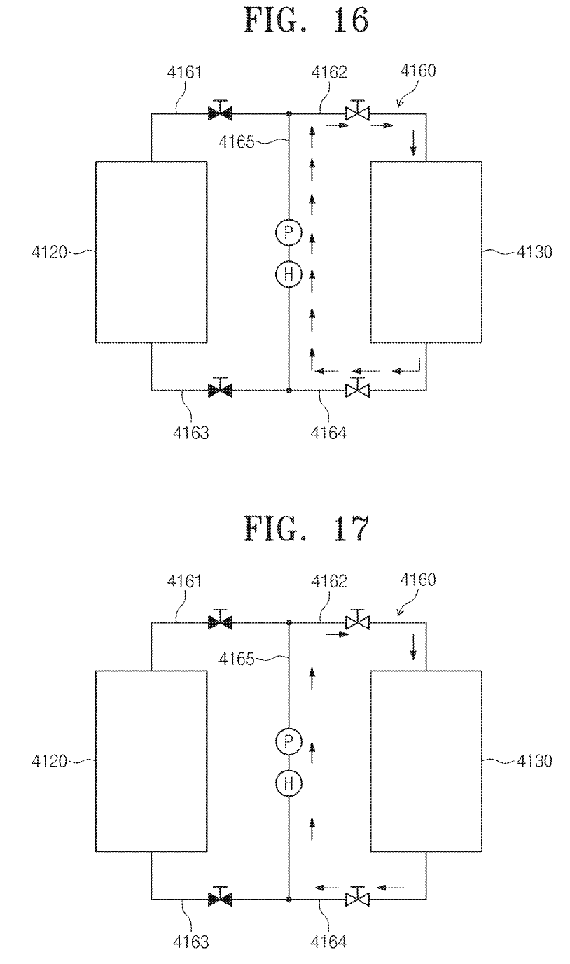

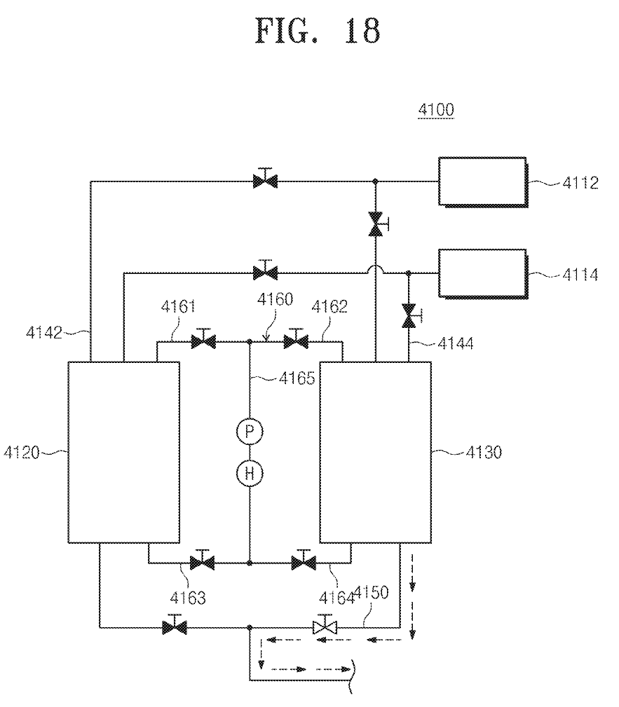

FIGS. 16 and 17 illustrate the circulation of the chemicals in the first mode and the second mode, respectively. In FIGS. 16 and 17, flows of the chemicals in the same time are shown and the number of arrows is proportional to strokes per minute of the pump 4172. The controller 4180 controls the pump 4172 to be in the first mode as shown in FIG. 16 till satisfying the process condition. When satisfying the process condition, as shown in FIG. 17, it is converted into the second mode to circulate the chemicals. In the second mode, the strokes per minute of the pump 4172 are controlled to be lower than the first mode. As an example, the strokes per minute may be controlled to be from about 70 to about 100 spm in the first mode and may be controlled to be from about 10 to 30 spm in the second mode. Also, in the second mode, the heater 4174 is controlled to be at a lower temperature than the first mode. As an example, the heater 4174 may be controlled to be at a process temperature in the second mode and may be controlled to be at a temperature higher than the process temperature. Accordingly, in the second mode, an energy consumption amount is smaller than the first mode. After that, as shown in FIG. 18, the chemicals in the second tank 4130 are supplied to the nozzle unit 380 through the chemical discharge line 4150.

According to the embodiment for controlling a supplying state according to a supplying mode, a discharge mount of carbon dioxide may be reduced by about 2.71 g/wafer totally from about 234.82 g/wafer to about 232.11 g/wafer.

In the embodiment, the chemical supplying unit 4100 including the first tank 4120 and the second tank 4130 has been described. However, this is just an example for allowing the present invention to be understood and is not limited thereto but may be similarly applied to a case of including one tank. Although not shown in the drawings, it may be similarly applied to a case of including three or more tanks.

According to the embodiments, a substrate treatment apparatus capable of controlling and reducing energy by changing strokes of a pump per minute may be provided.

Effects of the present invention are not limited to the described above, and effects not mentioned above will be clearly understood by a person of ordinary skill in the art from the specification and the attached drawings.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A method of treating a substrate in a substrate treating apparatus, the method comprising:
supplying chemicals from a tank;
circulating the chemicals through a circulation line connected to the tank;
maintaining the substrate in a first mode until a process condition is satisfied; and
switching the apparatus to a second mode different from the first mode after satisfying the process condition, the apparatus consuming a smaller amount of energy in the second mode than in the first mode.

2. The method of claim 1, wherein the circulation line is installed with a heater configured to control a temperature of the chemicals, and
wherein the temperature is lower in the second mode in the first mode.

3. The method of claim 1, wherein the circulation line is installed with a pump configured to control a flow amount of the chemicals, and
wherein strokes per minute of the pump are lower in the second mode in the first mode.

4. The method of claim 1, wherein the circulation line is installed with a pump configured to control a flow amount of the chemicals and a heater configured to control a temperature of the chemicals, and
wherein strokes per minute of the pump and the temperature are lower in the second mode in the first mode.
